(19) United States
(12) Patent Application Publication
(10) Pub. No.: US 2014/0183714 A1
(43) Pub. Date: Jul. 3, 2014

(54) DIE PACKAGE STRUCTURE

(71) Applicant: Innovative Turnkey Solution Corporation, Hsinchu City (TW)

(72) Inventor: Shih-Chi CHEN, Hsinchu City (TW)

(21) Appl. No.: 13/910,477

(22) Filed: Jun. 5, 2013

(30) Foreign Application Priority Data
Dec. 28, 2012 (TW) 101225509

(51) Int. Cl. H01L 23/495; H01L 23/498

(52) U.S. Cl. CPC H01L 23/49575; H01L 23/49861
USPC 257/676

(57) ABSTRACT

A die packaged structure is provided, which includes a die having the pad disposed on one side of the active surface. A packaged substrate having a front surface and a back surface, and the connecting terminal disposed on one side of the packaged substrate region, and passed through the packaged substrate region. An opening is disposed between the connecting terminal and one side of the packaged substrate region. Then, the back surface of the packaged substrate is fixed on die by an adhesive layer, such that the pad is exposed on the opening of the packaged substrate region. A conductive wire is electrically connected the pad with the connecting terminal, and a packaged body is encapsulated the packaged substrate region, the die and the conductive wire, and the external connecting terminal is exposed on the packaged substrate region. A conductive component is arranged on the external connecting terminal.

### FIELD OF THE INVENTION

The present invention relates to a die packaged structure which is formed by wafer level packaging process and simple wire bonding process, and in particular to a flash memory utilizes wire bonding process to form a die packaged structure.

### BACKGROUND OF THE INVENTION

The development of semiconductor technology is very fast, in particular, a semiconductor dices tends to miniaturization of the tendency. However, the function requirement of semiconductor dice also tends to the diversification. In other words, a smaller region of the semiconductor dice requires more input/out pads so as to the density of the pins is increased quickly. Thus, the semiconductor dices is difficult to package and the yield is to be decreased.

The mainly propose of the packaged structure is for preventing the die from the damage. However, each the plurality of dies is formed by cutting the wafer, and packaging and testing each the plurality of dies. In addition, another package technology is called “Wafer Level Package, WLP”, which is used to package before the wafer is cut into a plurality dies. The wafer level package technology has several advantages such as short production cycle, lower cost, and no under-filler.

### SUMMARY OF THE INVENTION

The mainly objective of the present invention is to provide a die packaged structure. The plurality of packaged substrate regions is formed on the circuit board, and each plurality of packaged substrate regions is fixed on each the plurality of dies on the wafer after alignment, such that each the plurality of pads on one side of each plurality of dies is electrically connected with the plurality of connecting terminals on the packaged substrate region, and the plurality of external connecting terminals is exposed on the packaged substrate region after packaging process. Then, a sawing process is performed to cut the wafer to obtain the plurality of die packaged structure having a substrate.

Another objective of the present invention is to provide a die packaged structure, particularly to suitable for large scale die packaged process, such as memory, in particular to an NAND flash memory chip, NOR flash memory chip, communication IC chip, and several application-specific IC chip.

An objective of the present invention is to provide a die packaged structure, a plurality of external connecting terminals is exposed on one surface of the die packaged structure to be endpoint to connect with external component. With respect to the other surface of the plurality of external connecting terminals is the back surface of the die. Thus, the die packaged structure can achieve good heat dissipation effect, and good heat dissipation is very important for large scale IC.

According to above objectives, the present invention provides a die packaged structure, which includes a die having an active surface and a back surface, and a plurality of pads is disposed on one side of the active surface of each the plurality of dies. A plurality of connecting terminals is disposed on one side of the package substrate region, and is passed through the back surface and front surface of the packaged substrate region. An opening is disposed on one side of the packaged substrate region, and a plurality of external connecting terminals is disposed on another side adjacent to the plurality of connecting terminals. Then, the back surface of the packaged substrate region is fixed on the die by the adhesive layer, such that the plurality of pads on one side of the die is exposed on the opening of the packaged substrate region. A plurality of conductive wires is electrically connected the plurality of connecting terminals on one side of the packaged substrate region with the plurality of pads on one side of the die. A packaged body is encapsulated the packaged substrate region, the die and the plurality of conductive wires, and the plurality of external connecting terminals on the packaged substrate is to be exposed. A plurality of connecting components is arranged on the plurality of external connecting terminals.

The present invention also provides another die packaged structure, which includes a die having an active surface and a back surface, and a plurality of pads on one side of the active surface of the die. A packaged substrate region having a front surface, and a plurality of connecting terminals is disposed on one side of the packaged substrate region and is passed through the front surface and the back surface of the packaged substrate region. An opening is disposed between the plurality of connecting terminals and one side of the packaged substrate region, and a plurality of external connecting terminals is disposed one side adjacent to the plurality of connecting terminals on the packaged substrate region. Then, the back surface of the packaged substrate is fixed on the die by an adhesive layer, such that the plurality of pads on one side of the die is exposed on the opening of the packaged substrate region, and a plurality of external connecting terminals extended outwardly is larger than the side of the die. A plurality of conductive wires is electrically connected the plurality of connecting terminals on one side of the packaged substrate region with the plurality of pads on one side of the die. A packaged body is encapsulated the packaged substrate region, the active surface of the die and the plurality of conductive wires, and the plurality of external connecting terminals is to be exposed on the outside of the packaged body.

### BRIEF DESCRIPTION OF THE DRAWINGS

The present invention will be apparent to those skilled in the art by reading the following description of a preferred embodiment thereof with reference to the drawings, in which:

FIG. 1 is a vertical view of a wafer having a plurality of dies thereon.

FIG. 2A is a vertical view of a front surface of packaged substrate.

FIG. 2B is a vertical view of a back surface of the packaged substrate.

FIG. 3 is a vertical view of FIG. 2A and FIG. 2B of the packaged substrate region is combined with the die, and the packaged substrate region having the plurality of connecting terminals and the plurality of traces thereon.

FIG. 4 is a cross-sectional view of a packaged substrate region is disposed on the die.

FIG. 5A is a cross-sectional view of Y1-Y1 direction in FIG. 4.

FIG. 5B is a cross-sectional schematic diagram illustrates a packaged material that is encapsulated the packaged substrate region, the plurality of metal wires, and portion active surface of the die, and the plurality of external connecting terminals is to be exposed.

FIG. 5C is a cross-sectional view of Y2-Y2 direction in FIG. 4.

FIG. 5D is a cross-sectional schematic diagram illustrates an electroplating process is performed on the back surface of packaged substrate region.

FIG. 6 is a vertical view of a packaged substrate region is disposed on the die.

FIG. 7A is a cross-sectional schematic diagram illustrates a Y1-Y1 direction in FIG. 4, and shows the packaged substrate region stacked on the die and the plurality of external connecting terminals is exposed outside of the die.

FIG. 7B is a cross-sectional schematic diagram illustrates a packaged material encapsulated the packaged substrate region and the die, and the plurality of external connecting terminals on one side of the packaged substrate region is exposed outside of the die by screen printing process.

FIG. 8 is a cross-section schematic diagram illustrates a stamping process is performed on the plurality of external connecting terminals of the packaged substrate region to form like a lead frame having an inner lead and an outer lead.

### DETAILED DESCRIPTION OF THE PREFERRED EMBODIMENT

The present invention provides a die packaged structure, in particular to a wafer level packaged structure is formed by using simple wire bonding process, and thus, such wafer level packaged structure can be referred to Wire-bonding Chip Scale Package (WBCSP), which can apply for large chip packaged structure. The cost can also be saved due to the simple packaged structure.

Some of the detail embodiments of the present invention will be described below. However, beside the detail description, the present invention can be generally used in other embodiments.

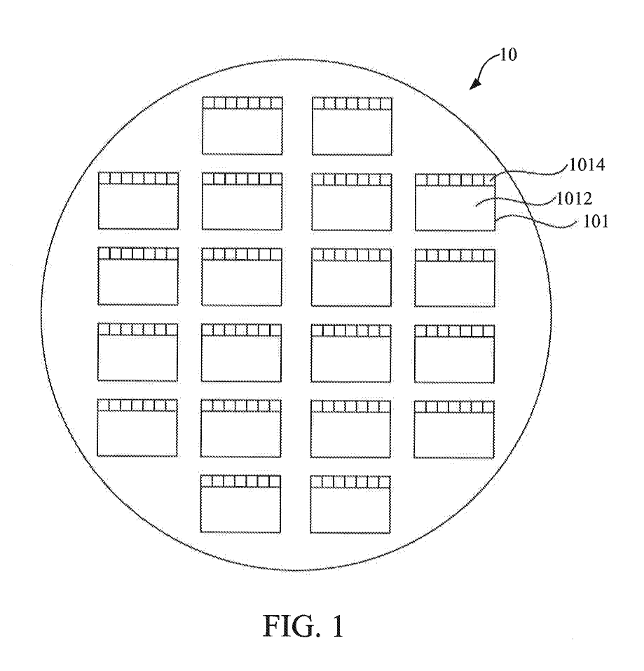

Please refer to FIG. 1. FIG. 1 is a vertical view of a wafer having a plurality of dies. As shown in FIG. 1, the wafer 10 has a plurality of dies 101 thereon. Each the plurality of dies 101 has an active surface 1012 and a back surface (not shown). A plurality of pads 1014 is disposed on one side of the active surface 1012 of the die 101, in which each the plurality of pads 1014 is formed by redistribution layer process. It is noted to illustrate that the plurality of dies 101 of the wafer 10 has completed the semiconductor manufacturing process, and each the plurality of dies 101 such as NAND flash memory, NOR flash memory, communication IC or application-specific IC, which can be formed by large scale chip manufacturing process.

In the embodiment of the present invention with the flash memory to illustrate, in particular to a NAND flash memory with 48 pins. In addition, the manufacturing process and the redistribution layer process is not a main feature in this present invention, and thus it will not describe herein.

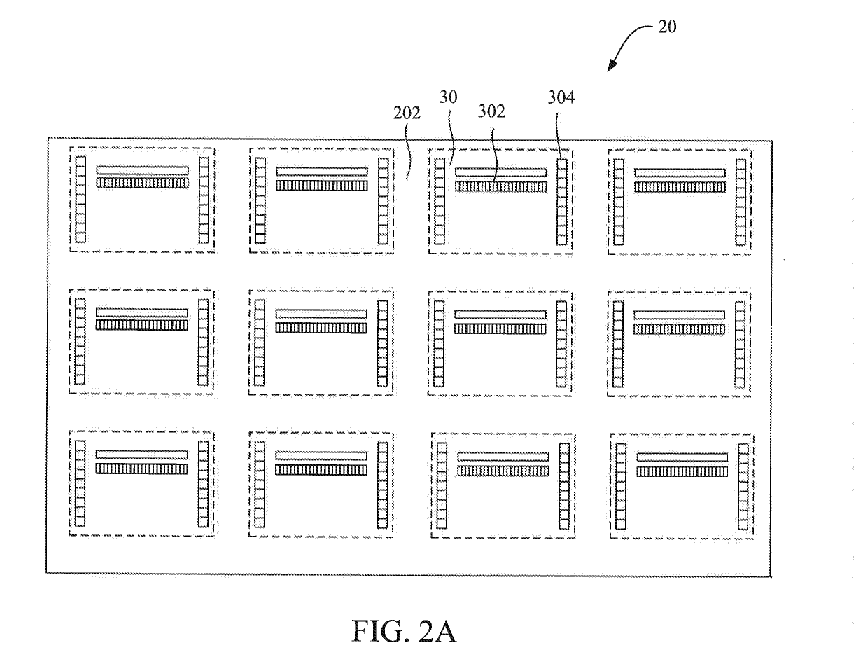

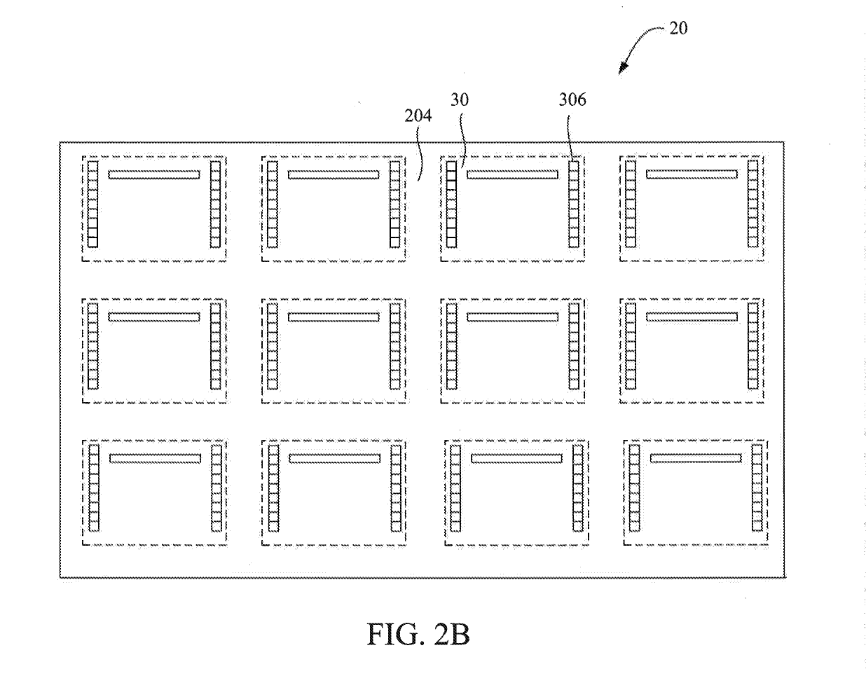

Then, please refer to FIG. 2A. FIG. 2A is a vertical view of a front surface of the circuit board which has a plurality of packaged substrate regions. In FIG. 2A, a circuit board 20 is provided with a front surface 202 and a back surface 204 (as shown in FIG. 2B). A plurality of packaged substrate regions 30 is arranged in array on the front surface 202 of the circuit board 20, in which each the plurality of packaged substrate regions 30 includes a front surface which is equivalent to the front surface 202 of the circuit board 20, and a back surface which is equivalent to the back surface 204 of the circuit board 20. A plurality of connecting terminals 302 is arranged on one side 32 of each the plurality of packaged substrate regions 30, and is passed through the front surface and the back surface of the packaged substrate region 30, and an opening 31 is disposed between the plurality of connecting terminals 302 and one side of the packaged substrate region 30, such that when the packaged substrate region 30 is combined with the die 101, the plurality of pads 1014 on one side of the die 101 can be exposed out of the opening 31. A plurality of external connecting terminals 304 is arranged on one side 34 adjacent to the plurality of connecting terminals 302. The plurality of connecting terminals 302 of the present invention can be golden finger or metal trace. When the plurality of connecting terminals 302 is golden finger, each the plurality of connecting terminals 302 can be isolated from each other by an insulating material (for example, plastic material) (not shown) or ceramic (not shown).

In addition, in this embodiment, the circuit board 20 can be a flexible print circuit board or a rigid substrate. Furthermore, for the rigid substrate, the circuit substrate 20 can be a single layer print circuit board (PCB) or a multi-layer print circuit board. For the flexible print circuit board which can be made of polymeric material and lead frame.

Next, please refer to FIG. 2B. FIG. 2B is a vertical view of showing a back surface of the circuit board that has a plurality of packaged substrate regions thereon. In FIG. 2B, the back surface 204 of the circuit board 20 has a plurality of connecting terminals 306 thereon. The arrangement of the plurality of connecting terminals 306 is disposed corresponds to a plurality of connecting terminals 202 on the front surface of the circuit board 20, in which the plurality of connecting terminals 302 on the front surface 202 of the circuit board 20 is electrically connected with the plurality of connecting terminals 306 on the back surface 204 of the circuit board 20. It is noted to illustrate that the plurality of connecting terminals 302 and the plurality of connecting terminals 306 are the same connecting terminal, and are passed through the front surface 202 and the back surface 204 of the circuit board 20. In addition, the plurality of connecting terminals 306 on the back surface 204 of the circuit board 20 can be a pad or a bump.

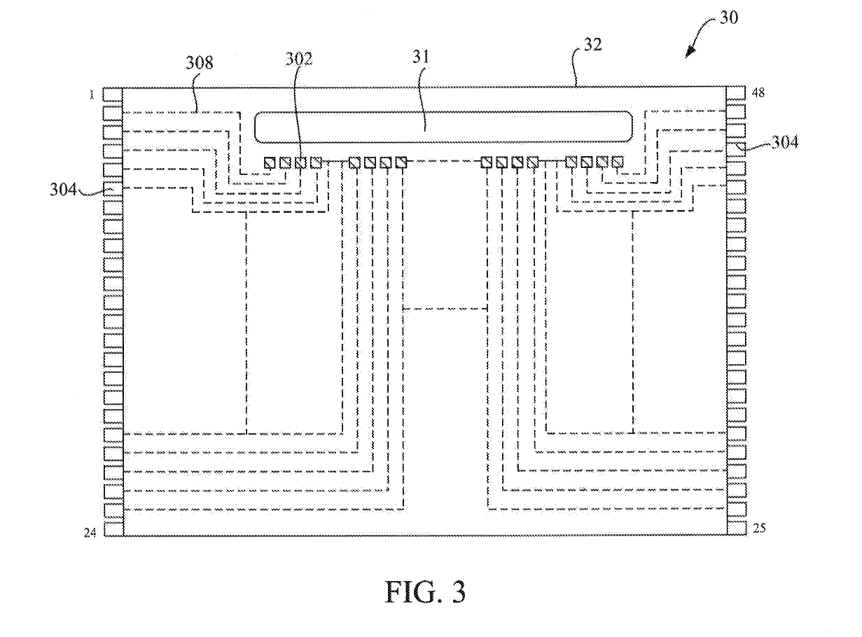

Then, please refer to FIG. 3. FIG. 3 is a vertical view of FIG. 2A which illustrates one of the plurality of packaged substrate region having a plurality of connecting terminals and a plurality of traces thereon. In FIG. 3, the circuit board 20 has a plurality of packaged substrate regions 30, and one side 32 of the front surface 202 of each the plurality of packaged substrate regions 30 has a plurality of connecting terminals 302, and an opening 31 is disposed on the side 32 of the packaged substrate region 30. In addition, a plurality of external connecting terminals 304 is disposed on one side adjacent to the plurality of connecting terminals 302. The plurality of connecting terminals 302 is electrically connected with the plurality of external connecting terminals 304 by a plurality of traces 308.

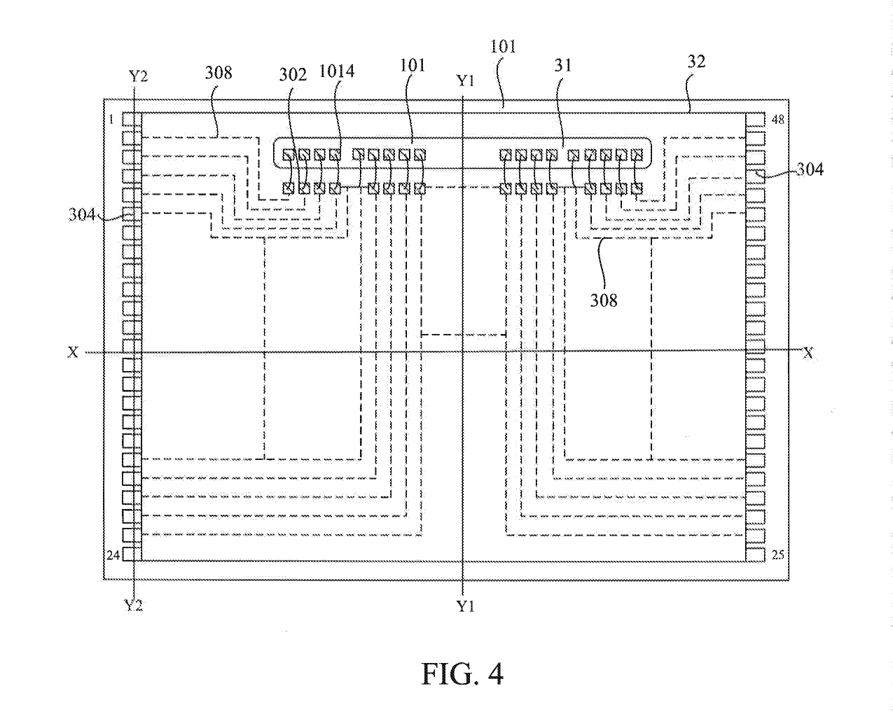

Next, please referrer to FIG. 4. FIG. 4 is a vertical view of a packaged substrate region disposed on the die. First, it is noted to that the formation steps of the die packaged structure is formed by each the plurality of packaged substrate regions 30 of the circuit board 20 disposed on each the plurality of die 101 of the wafer 10 with using wafer level packaging process, and each the plurality of packaged substrate regions 30 is corresponds to each the plurality of die 101 of the wafer 30. The present invention utilizes one of the plurality of dies 101 and one of the plurality of packaged substrate regions 30 to illustrate the formation steps of the die packaged structure. Herein, the die packaged structure is identical whether the die packaged structure is stacked by using a single packaged substrate region 30 and a die 20, or the die packaged structure is stacked by entire circuit board 20 and entire wafer 10. The different is that a sawing process is performed to cut the entire wafer level packaged structure which is formed by the entire circuit stacked on the entire wafer to obtain a plurality of die packaged structures.

In addition, in this embodiment, the plurality of pads 1014 on the one side 32 of the die 101 is exposed out of the opening 31 of the packaged substrate region 30 due to the size of the packaged substrate region 30 is smaller than that of the die 101, when the back surface 204 (can be regards as the back surface 204 of the circuit board 20) of the packaged substrate region 30 is fixed on the die 101. Moreover, the length of each the plurality of external connecting terminals 304 can be larger than or is equal to that of one side of the die 101.

Please also refer to FIG. 4. Each the plurality of connecting terminals 302 on the packaged substrate region 30 and the plurality of pads 1014 of the die 101 are exposed and are arranged in an array when the packaged substrate region 30 is fixed on the die 101. Then, the plurality of conductive wires 40 is formed on each the plurality of connecting terminals 302 on one side 32 of the packaged substrate region 30 and on each the plurality of pads 1014 on one side (now shown) of the die 101 respectively by wire bonding process, such that the die 101 can electrically connect with corresponding packaged substrate region 30.

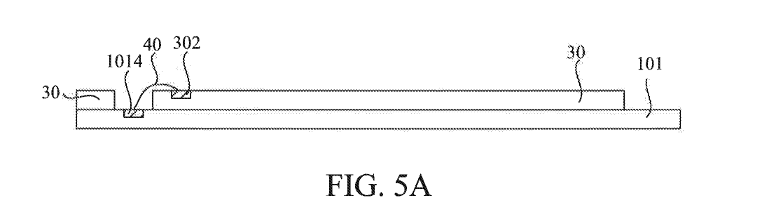

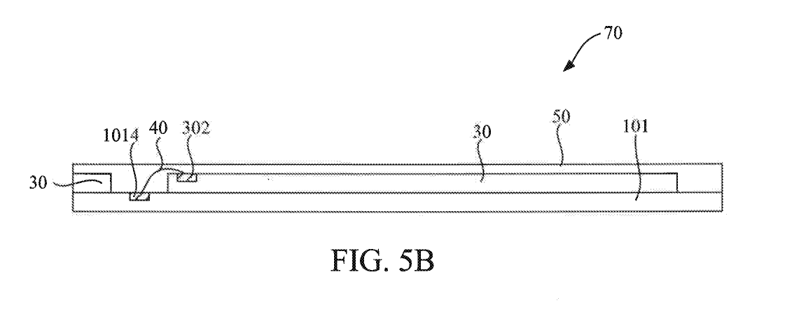

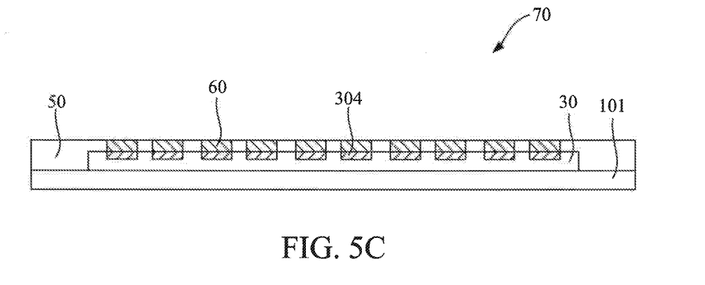

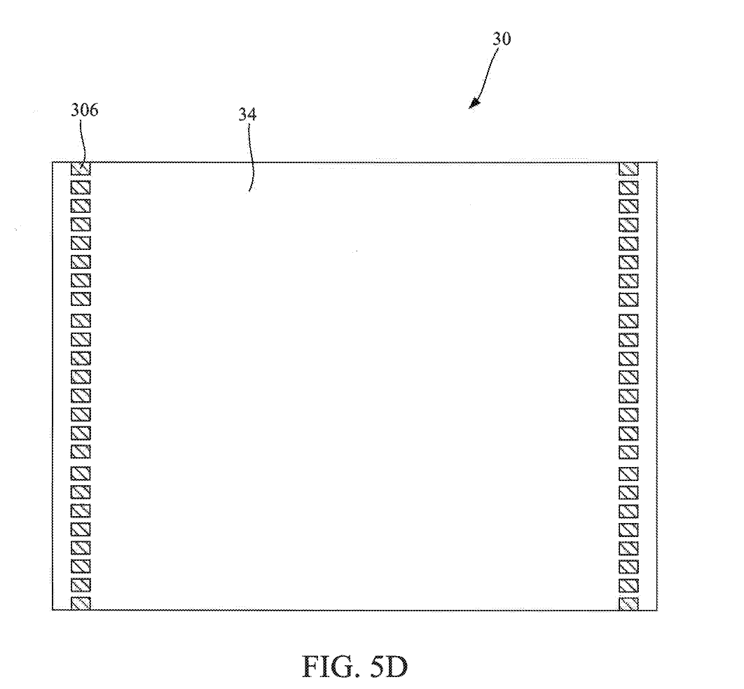

Please refer to FIG. 5A. FIG. 5A is a cross-sectional diagram of Y1-Y1 direction in FIG. 4. FIG. 5A is Y1-Y1 direction cross-sectional view of the packaged substrate region 30 that is arranged on the die 101 after wire bonding process is completed. Then, refer to FIG. 5B. In FIG. 5B, a packaged material 50 is formed on the packaged substrate region 30 to encapsulate the packaged substrate region 30, the plurality of conductive wires 40, and the portion active surface 1012 of the die 101 by screen printing process, and then the plurality of external connecting terminals 304 is to be exposed.

Please refer to FIG. 5C. FIG. 5C is a cross-sectional view of Y2-Y2 direction in FIG. 4. In FIG. 5C, it can be obtained that the packaged substrate region 30 has the plurality of external connecting terminals 304 in Y2-Y2 direction (which is cross-sectional of the plurality of external connecting terminals 304) after the wire bonding process is completed. In FIG. 5C, the plurality of external connecting terminals 304 can be optionally exposed (that is to say, the packaged body 50 is not encapsulated the plurality of external connecting terminals 304), or the plurality of external connecting terminals 304 is encapsulated by a packaged body 50 first, and then the plurality of external connecting terminals 304 is exposed by using semiconductor manufacturing process. The formation steps of the packaged body 50 is not to be limited in this invention, in addition, the material of the packaged body 50 is also not to be limited herein.

Please also refer to FIG. 5C. A plurality of conductive components 60 is disposed on the plurality of external connecting terminals 304 on the packaged substrate region 30 by an electroplating process after the screen printing process is finished, and then the plurality of external connecting terminals 304 is to be exposed. The height of the plurality of conductive components 60 is larger than or is equal to total height of the packaged substrate region 30 and the packaged body 50. In addition, the plurality of conductive components 60 can be the bump which is formed by bump process.

It is noted to illustrate that FIG. 5C is a cross-sectional view of Y2-Y2 direction in FIG. 4, such that the packaged body 50 is disposed between each the plurality of external connecting terminals 304 of the packaged substrate region 30, and each the plurality of conductive components 60 is disposed on each the plurality of external connecting terminals 304.

Then, FIG. 5D is a cross-sectional view of a back surface of the packaged substrate region after completing the electroplating process. In FIG. 5D, the plurality of external connecting terminals 304 is arranged inside of the die packaged structure 70. It is obviously to obtain that the die packaged structure 70 of the invention, the plurality of external connecting terminals 304 is exposed on one surface of the die packaged structure 70 and can be used as a connecting endpoint to electrically connect with the external component (not shown), and another surface is the back surface 1012 of the die 101 which can be used as the heat dissipation to achieve good heat dissipation effect, and is very important for the large scale IC.

It is noted to illustrate that although the die packaged structure 30 is formed by a single packaged substrate region 30 and a single die 101 according to above FIG. 1 to FIG. 5D, but in fact, the packaging process is performed by using an entire circuit board 20 arranged on an entire wafer 10 during the packaging process. Thus, the entire wafer level packaged structure is accomplished by electroplating the plurality of conductive components 60 on the plurality of external connecting terminals 304 on the circuit board 20 by electroplating process. Finally, the wafer level packaged structure is cut into a plurality of die packaged structures 70 by a sawing process. In this embodiment, the plurality of die packaged structures 70 is especially for flash NAND memory packaged structure.

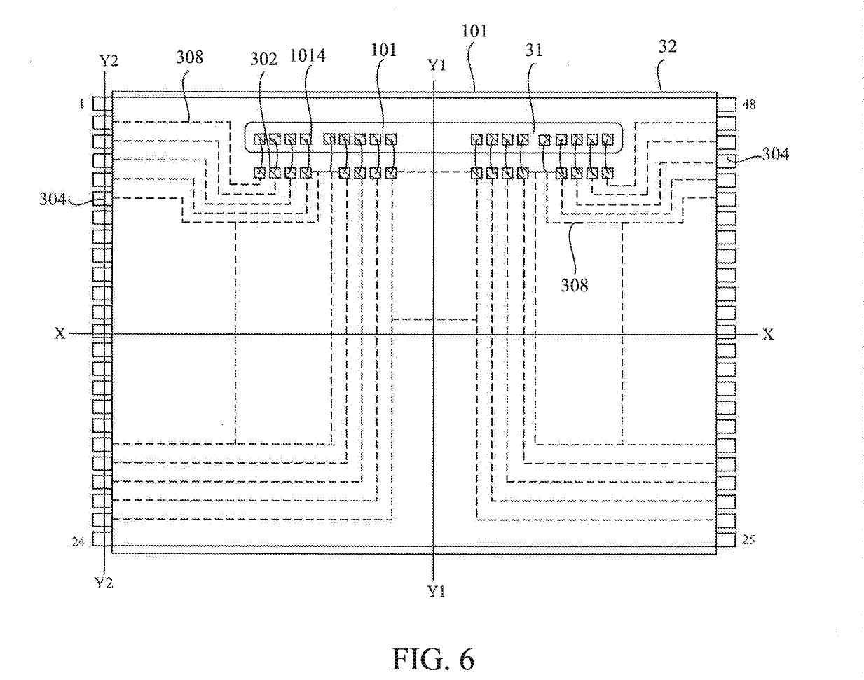

in addition, the present invention also provides another embodiment of the die packaged structure, in which the manufacturing process is similar to above FIG. 1 to FIG. 5B, and it would not be described herein. The different between abovementioned is that if the cross-sectional view in X-X direction in FIG. 6, the packaged substrate region 30 has a plurality of external connecting terminals 304 that is disposed on the die 101, in which the length of each the plurality of external connecting terminals 304 is larger than that of the one side of the die 101.

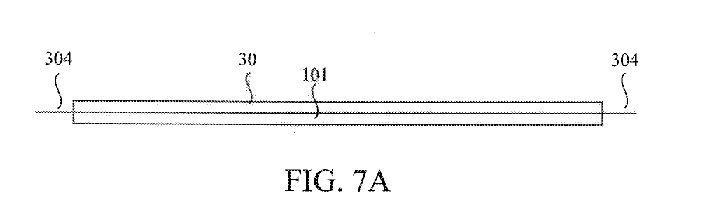

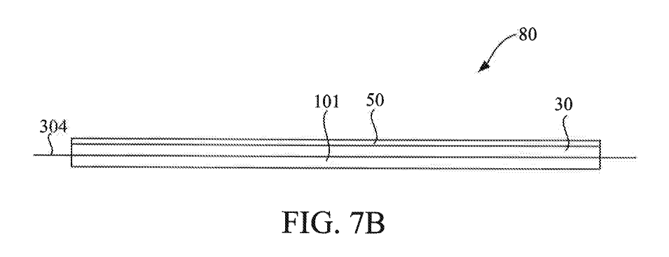

Next, please refer to FIG. 7B. FIG. 7B is a cross-sectional schematics diagram illustrates a packaged body 50 is formed to encapsulate the packaged substrate region 30 and the die 101, and the plurality of external connecting terminals 304 on one side 32 of the packaged substrate region 30 is exposed out of the packaged body 50. Herein, FIG. 7B merely shows the packaged substrate region 30 and the die 101 which is encapsulated by the packaged body 50, and the plurality of external connecting terminals 304 is exposed out of the packaged body 50, but the plurality of pads 1014 of the die 101 and the plurality of conductive wires 40 which is electrically connected the packaged substrate region 30 with the die 101 that cannot be shown in FIG. 7B.

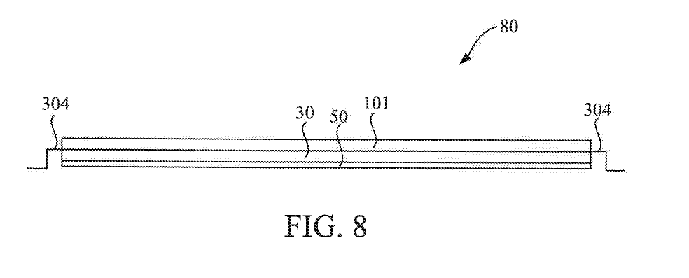

Then, please refer to FIG. 8. FIG. 8 shows a lead frame with an inner lead and an outer lead which is formed by stamping a plurality of external connecting terminals of the packaged substrate region with stamping process. In FIG. 8, a sawing process is performed to cut the above wafer level packaged structure to obtain the plurality of die packaged structures 70. In this embodiment, for each the plurality of die packaged structures 80 can electrically connect with other components (not shown), and the plurality of external connecting terminals 304 of each the plurality of die packaged structures 80 is stamped to form like a structure of a lead frame with the inner lead and the outer lead. Thus, each the plurality of die packaged structures 80 can electrically connect with external component (not shown) via the inner lead (not shown) and the outer lead (not shown).

Although the present invention has been described with reference to the preferred embodiment thereof, it is apparent to those skilled in the art that a variety of modifications and changes may be made without departing from the scope of the present invention which is intended to be defined by the appended claims.

What is claimed is:

1. A die packaged structure, comprising:
a die, said die having an active surface and a back surface, and a plurality of pads is disposed on one side of said active surface of said die;
a packaged substrate region, said packaged substrate region having a front surface and back surface, a plurality of connecting terminals disposed on one side of said packaged substrate region and is passed through said front surface and said back surface of said packaged substrate region, and a plurality of external connecting terminals is disposed on another side adjacent to said plurality of connecting terminals;
said back surface of said packaged substrate region is fixed on said die by an adhesive layer and said plurality of pads is exposed on said opening of said packaged substrate region;
a plurality of conductive wires, said plurality of conductive wires is electrically connected said plurality of connecting terminals with said plurality of pads;
a packaged body, said packaged body encapsulated said packaged substrate region, said active surface of said die and said plurality of conductive wires, and said plurality of external connecting terminals adjacent to said plurality of connecting terminals on said side of said packaged substrate region is exposed; and
a plurality of conductive components, said plurality of conductive components is arranged on and is electrically connected with said plurality of connecting terminals.

2. The die package structure according to claim 1, wherein said packaged substrate region is a print circuit board.

3. The die package structure according to claim 1, wherein the size of said print circuit board is smaller than that of said die.

4. The die package structure according to claim 1, wherein said packaged substrate region is a flexible print circuit board.

5. The die package structure according to claim 1, wherein the size of said packaged substrate region is smaller than that of said die.

6. The die package structure according to claim 1, wherein height of said plurality of conductive components is identical to a total height of said packaged body.

7. A die package structure, comprising:
a die, said die having an active surface and a back surface, and a plurality of pads disposed on one side of said active surface of said die;
a packaged substrate region, said packaged substrate region having a front surface and a back surface, a plurality of connecting terminals disposed on one side of said packaged substrate region and is passed through said front surface and said back surface of said packaged substrate region, an opening is disposed between said plurality of connecting terminals and said side of said packaged substrate region, and, a plurality of external connecting terminals disposed one side adjacent to said plurality of connecting terminals;
said back surface of said packaged substrate region is fixed on said die by an adhesive layer, such that said plurality of pads exposed out of said opening of said packaged substrate region, and said die and a length of said plurality of external connecting terminals is extended outwardly larger than that of said side of said die;
a plurality of conductive wires, said plurality of conductive wires is electrically connected said plurality of connecting terminals on said side of said packaged substrate region with said plurality of pads on said side of said die; and
a packaged body, said packaged body encapsulated said packaged substrate region, said active surface of said die and said plurality of conductive wires, and said plurality of external connecting terminals being exposed on an outside of said packaged body.

8. The die packaged structure according to claim 7, wherein said packaged substrate region is a print circuit board.

9. The die packaged structure according to claim 8, wherein a size of said packaged substrate region is smaller than that of said die.

10. The die packaged structure according to claim 7, wherein said packaged substrate region is a flexible print circuit board.

11. The die packaged structure according to claim 7, wherein a size of said packaged substrate region is smaller than that of said die.

12. The die packaged structure according to claim 7, wherein said plurality of external connecting terminals is a lead frame, and said lead frame includes an inner lead and an outer lead.
